(19) United States
(12) Patent Application Publication
(10) Pub. No.: US 2006/0134948 A1
(43) Pub. Date: Jun. 22, 2006

(54) Wiring board-stacking structure

(75) Inventors: Masaki Yamamoto, Ogasa-gun (JP); Hiroyasu Furuya, Ogasa-gun (JP)

Correspondence Address: SUGHRUE MION, PLLC, 2100 PENNSYLVANIA AVENUE, N.W., SUITE 800, WASHINGTON, DC, 20037, US

(73) Assignee: YAZAKI CORPORATION

(21) Appl. No.: 11/298,479

(22) Filed: Dec. 12, 2005

(30) Foreign Application Priority Data
Dec. 16, 2004 (JP) P2004-363769

(51) Int. Cl. H05K 1/00

(52) U.S. Cl. 439/76.2

(57) ABSTRACT

In a structure of stacking a plurality of wiring boards 1 and 10 each having bus bars 6, 14 received in bus bar receiving grooves 3, 12 formed in an upper surface thereof, movement prevention bosses 13 for preventing the movement of the bus bars 14 are formed on the upper surface of the second wiring board 10, and more specifically are formed on peripheral edge portions of the bus bar receiving grooves 12. Boss escape portions 5 are formed in a lower surface of the first wiring board 1 disposed above the second wiring board 10, and the movement prevention bosses 13 on the second wiring board 10 are received respectively in the boss escape portions 5.

### BACKGROUND OF THE INVENTION

1. Field of the Invention

This invention relates to a wiring board-stacking structure of stacking a plurality of wiring boards each having bus bars installed thereon.

2. Related Art

Among electric connection boxes for an automobile or the like, there is the type of electric connection box in which a plurality of wiring boards (each having bus bars installed thereon), stacked together, are contained, for example, as shown in Unexamined Japanese Utility Model Publication 6-41322.

Among the wiring boards 50, the uppermost wiring board 50 has bus bar receiving grooves 51 formed in an upper surface thereof, and bus bar-fixing bosses 52 are formed on this upper surface at peripheral edge portions of the bus bar receiving grooves 51, as shown in FIG. 5. Bus bars (not shown) are received in the bus bar receiving grooves 51, and then the bus bar-fixing bosses 52 are crushed or deformed by melting or other, thereby fixing the bus bars. In FIG. 5, reference numeral 53 denotes dummy bosses.

However, the wiring board 50 has such a form that the bus bar-fixing bosses 52 project from the upper surface of the wiring board 50, and therefore there has been encountered a problem that the thickness of the stack of wiring boards increases. And besides, many bus bar-fixing bosses 52 need to be crushed or deformed, and therefore there has been encountered a problem that the efficiency of the operation is low. Therefore, the wiring board 50 of the above construction has been used only for the uppermost wiring board, while the type of wiring board which has only bus bar-receiving grooves, and does not have any projecting boss has been used for each of the other wiring boards disposed below the uppermost wiring board 50. Namely, the bus bars, installed on any of the wiring boards other than the uppermost wiring board, are held by the wiring board, disposed immediately above it, from the upper side, and therefore any bus bar-fixing boss does not need to be formed on each of the wiring boards other than the uppermost wiring board. And, when such bus bar-fixing bosses are formed on the wiring boards other than the uppermost wiring board, the overall thickness of the stack of wiring boards increases.

However, in the process of assembling the plurality of conventional wiring boards 50 together, each of the wiring boards 50 is put on a belt conveyor, and is conveyed. When the conveyance speed is changed, for example, at the time of starting and stopping the movement of the conveyor belt, an inertia force acts on each wiring board 50. Each of those wiring boards, disposed below the uppermost wiring board, has the bus bars merely received in the bus bar receiving grooves, and therefore there has been encountered a problem the bus bars spring out of the bus bar receiving grooves upon application of the inertia force.

### SUMMARY OF THE INVENTION

Therefore, this invention has been made in order to solve the above problem, and an object of the invention is to provide a wiring board-stacking structure, in which in a process of assembling wiring boards together, bus bars are prevented from springing out of bus bar receiving grooves in each wiring board, and besides an overall thickness of the stack of wiring boards can be prevented from increasing.

According to the present invention, there is provided a wiring board-stacking structure of stacking a plurality of wiring boards each having a bus bar received in a bus bar receiving groove formed in an upper surface thereof; provided in that bosses for preventing the movement of the bus bar are formed on the upper surface of each of the wiring boards, and boss escape portions are formed in a lower surface of the upper-side wiring board of any two adjacent wiring boards, and the bosses on the lower-side wiring board of the two adjacent wiring boards are received respectively in the boss escape portions formed in the upper-side wiring board.

The wiring board-stacking structure of the present invention is provided in that the bosses are formed on and project from a rib surrounding a periphery of the bus bar receiving groove.

In the present invention, when an inertia force acts on each wiring board, and tends to move the bus bar relative to the wiring board during the conveyance of the wiring boards by a belt conveyor, the movement of the bus bar is prevented by the movement prevention bosses. When the wiring boards are stacked together, the movement prevention bosses on the lower-side wiring board are received or fitted respectively in the boss escape portions formed in the wiring board disposed immediately above this lower-side wiring board. Therefore, each bus bar is prevented from springing out of the bus bar receiving groove in the process of assembling the wiring boards together, and besides the overall thickness of the stack of wiring boards can be prevented from increasing.

In the present invention, any hole for passing the movement prevention boss therethrough does not need to be formed through each bus bar.

### BRIEF DESCRIPTION OF THE DRAWINGS

FIG. 1 shows one preferred embodiment of the present invention, and is a perspective view of a structure of stacking a plurality of wiring boards, showing its disassembled condition.

FIGS. 2A and 2B show the above embodiment of the invention, and FIG. 2A is a perspective view showing a lower surface of a first wiring board, and FIG. 2B is a perspective view showing an upper surface of a second wiring board.

FIG. 3 shows the above embodiment of the invention, and is an enlarged view of a portion A in FIG. 2B.

FIG. 4 shows the above embodiment of the invention, and is a cross-sectional view of an important portion of the plurality of wiring boards stacked together.

FIG. 5 is a perspective view of a conventional wiring board.

### DETAILED DESCRIPTION OF THE PREFERRED EMBODIMENTS

One preferred embodiment of the present invention will now be described with reference to the drawings.

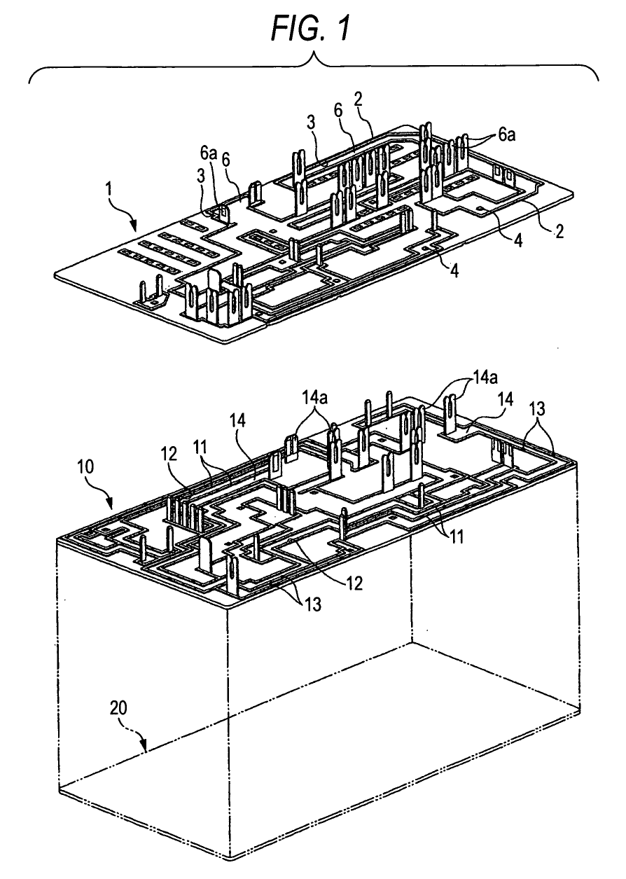

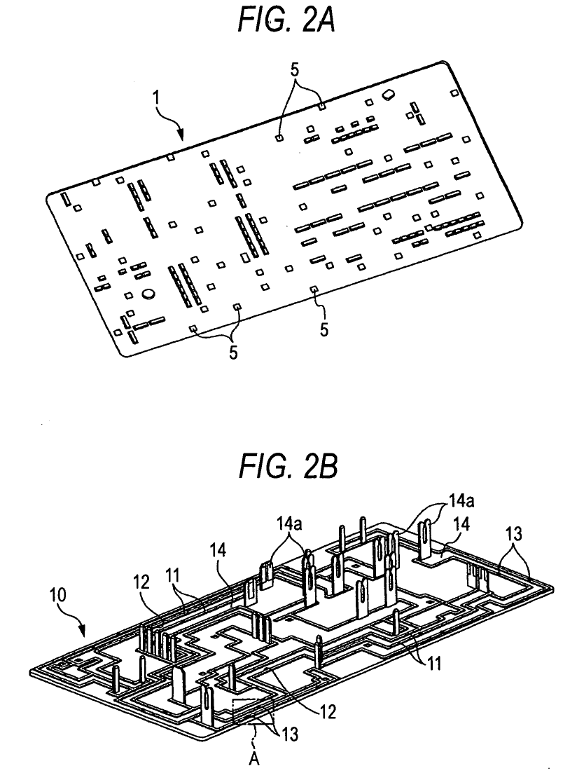

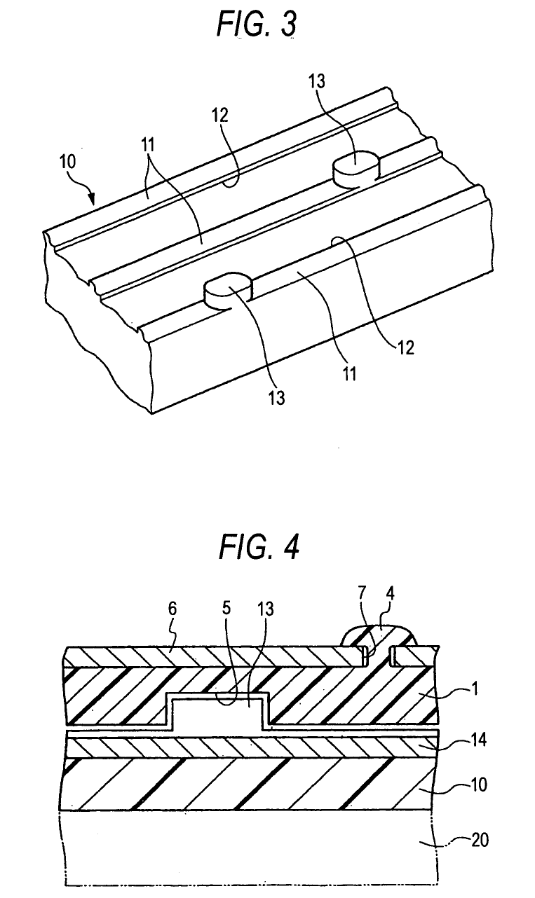

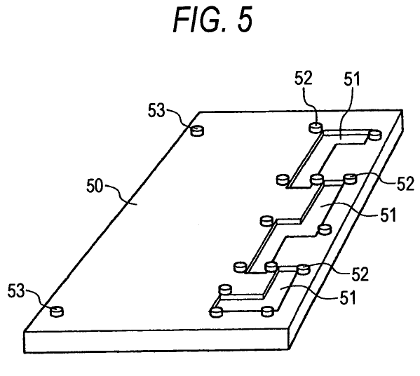

FIGS. 1 to 4 show one preferred embodiment of the invention, and FIG. 1 is a perspective view of a structure of stacking a plurality of wiring boards, showing its disassembled condition, FIG. 2A is a perspective view showing a lower surface of the first wiring board, FIG. 2B is a perspective view showing an upper surface of the second wiring board, FIG. 3 is an enlarged view of a portion A in FIG. 2B, and FIG. 4 is a cross-sectional view of an important portion of the plurality of wiring boards stacked together.

As shown in FIG. 1, three wiring boards 1, 10 and 20, each made of an insulative material, are stacked together in such a manner that opposed upper and lower surfaces of any two adjacent wiring boards are disposed in intimate contact with each other. Bus bar receiving grooves 3 are formed in the upper surface of the first wiring board (uppermost wiring board) 1, and are arranged in a predetermined pattern. Ribs 2 are formed on the upper surface of the first wiring board 1 in such a manner that an entire periphery of each of the bus bar receiving grooves 3 is surrounded by the corresponding rib 2. Bus bar-fixing bosses (movement prevention bosses) 4 are formed on and project respectively from suitable portions of a bottom surface of each bus bar receiving groove 3. As shown in FIG. 2A, a plurality of boss escape portions (boss receiving portions) 5, each in the form of a recess, are formed in the lower surface of the first wiring board 1. The plurality of boss escape portions 5 are so arranged as to be opposed respectively to movement prevention bosses 13 formed on the second wiring board 10 described later.

As shown in FIG. 1, the plurality of bus bars 6 are received in the bus bar receiving grooves 3, and by doing so, these bar bars 6 are installed on the upper surface of the first wiring board 1. As shown in FIG. 4, each bus bar 6 has boss insertion holes 7 which are to be disposed in registry with the corresponding bus bar-fixing bosses 4, respectively. Each of the bus bar-fixing bosses 4 extends through the corresponding boss insertion hole 7, and a projected distal end portion thereof is crushed or deformed by melting or other, thereby fixing each bus bar 6 to the upper surface of the first wiring board 1. Terminal portions 6a are formed on part of the plurality of bus bars 6, and these terminal portions 6a are disposed in an upstanding manner on the first wiring board 1.

As shown in FIGS. 1 and 2B, bus bar receiving grooves 12 are formed in the upper surface of the second wiring board 10 (which is disposed immediately beneath the first wiring board 1), and are arranged in a predetermined pattern. Ribs 11 are formed on the upper surface of the second wiring board 10 in such a manner that an entire periphery of each of the bus bar receiving grooves 12 is surrounded by the corresponding rib 11. Bus bars 14 are received respectively in the bus bar receiving grooves 12 formed in the upper surface of the second wiring board. Terminal portions 14a of the bus bars 14 are bent to project perpendicularly from the upper surface of the second wiring board 10.

As shown in FIG. 3, movement prevention bosses 13 for preventing the movement of the bus bars 14 are formed on the upper surface of the second wiring board 10, and more specifically are formed respectively on suitable portions of the ribs 11. When the three wiring boards 1, 10 and 20 are stacked together, the movement prevention bosses 13 are received respectively in the boss escape portions 5 formed in the lower surface of the first wiring board 1, as shown in FIG. 4. Boss escape portions (not shown) are formed in the lower surface of the second wiring board 10 as described above for the first wiring board 1. These boss escape portions are so arranged as to be opposed respectively to movement prevention bosses (not shown) formed on the third wiring board 20 described later.

As described above for the second wiring board 10, bus bar receiving grooves (not shown) are formed in the third wiring board 20 disposed immediately beneath the second wiring board 10, and also the movement prevention bosses (not shown) are formed in a projecting manner on the third wiring board 20. However, any boss escape portion is not formed in the lower surface of the third (lowermost) wiring board 20.

Namely, the movement prevention bosses 13 (not shown with respect to the third wiring board 20) for preventing the movement of the bus bars 14 are formed on the upper surface of each of the second and third wiring boards 10 and 20 (which are disposed below the first (uppermost) wiring board 1) at the peripheral edge portions of the bus bar receiving grooves 12 (not shown with respect to the third wiring board 20). Further, the boss escape portions 5 for respectively receiving the movement prevention bosses 13 on each of the third and second wiring boards 20 and 10 (which are disposed respectively below the second and first wiring boards 20 and 1) are formed in the lower surface of each of the second and first wiring boards 20 and 1 disposed above the third (lowermost) wiring board 20.

In the above construction, during the process of assembling the three wiring boards 1, 10 and 20 together, the first, second and third wiring boards 1, 10 and 20, each having the bus bars 6, 14 installed thereon, are conveyed by a belt conveyor. When an inertia force acts on each of the wiring boards 1, 10 and 20, and tends to move the bus bars 6, 14 relative to the wiring board 1, 10, 20 during the conveyance by the belt conveyor, the movement of the bus bars 6 on the first wiring board 1 is prevented by the bus bar-fixing bosses 4. Also, the movement of the bus bars 14 on each of the second and third wiring boards 10 and 20 is prevented by the movement prevention bosses 13. Therefore, during the process of assembling the wiring boards 1, 10 and 20 together, the bus bars 6, 14 are prevented from springing out of the bus bar receiving grooves 3, 12 in the wiring board 1, 10, 20. And besides, the height of the rib 11, formed at the peripheral edge portion of each bus bar receiving groove, is not increased over the entire length thereof, but the bosses 13 are formed respectively at the suitable portions of each rib 11 spaced from one another. Therefore, the boss escape portions 5 can be easily formed in each of the first and second wiring boards 1 and 10. Furthermore, when the wiring boards 1, 10 and 20 are stacked together, the movement prevention bosses 13 on the second wiring board 10 are received or fitted respectively in the boss escape portions 5 formed in the first wiring board 1 disposed immediately above the second wiring board 10, while the movement prevention bosses 13 on the third wiring board 20 are received or fitted respectively in the boss escape portions 5 formed in the second wiring board 10 disposed immediately above the third wiring board 20. Therefore, the overall thickness of the stack structure can be prevented from increasing.

Each of the boss escape portions 5, formed in the lower surface of each of the second and first wiring boards 10 and 1 (which are disposed above the third (lowermost) wiring board 20), has the recess-shape, and is generally equal in size to the boss 13, and therefore the sufficient strength of the second and first wiring boards 20 and 1 can be maintained. Namely, the boss escape portions 5 can also have the small size, and therefore the sufficient strength of the wiring boards 1, 10 and 20 can be maintained.

In this embodiment, the first wiring board 1, forming the uppermost layer, has the bus bar-fixing bosses 4 serving as the movement prevention bosses, and by crushing or deforming these bus bar-fixing bosses 4, the bus bars 6 are fixed to the first wiring board. Therefore, in the stacked condition of the wiring boards 1, 10 and 20, the bus bars 6, installed on the first (uppermost) wiring board 1, are positively fixed to the first wiring board 1 by the bus bar-fixing bosses 4.

The movement prevention bosses 13 are formed on and project from the ribs 11 each surrounding the corresponding bus bar receiving groove 12, and therefore any hole for passing the movement prevention boss 13 therethrough does not need to be formed through each bus bar 14. Therefore, the bus bar 14 is not complicated in construction.

In the wiring board-stacking structure of the above embodiment, although the three wiring boards are used, the invention can be applied to the case where the number of the wiring boards is two and also to the case where the number of the wiring boards is more than three.

What is claimed is:

1. A wiring board-stacking structure comprising:
a plurality of wiring boards stacked from each other, each having a bus bar received in a bus bar receiving groove formed in an upper surface thereof;
bosses for preventing the movement of said bus bar formed on the upper surface of each of said wiring boards; and
boss escape portions formed in a lower surface of the upper-side wiring board of any two adjacent wiring boards,
wherein said bosses on the lower-side wiring board of said two adjacent wiring boards are received respectively in said boss escape portions formed in said upper-side wiring board.

2. A wiring board-stacking structure according to claim 1, wherein said bosses are formed on and project from a rib surrounding a periphery of said bus bar receiving groove.
